(19) United States
(12) Patent Application Publication
(10) Pub. No.: US 2026/0344503 A1
(43) Pub. Date: Oct. 29, 2026

(54) LID FOR AIR CAVITY PACKAGES AND APPLICATIONS THEREOF

(71) Applicant: Qorvo US, Inc., Greensboro, NC (US)

(72) Inventors: Dennis Quaintance, Richardson, TX (US); Walid Meliane, Frisco, TX (US)

(21) Appl. No.: 19/555,635

(22) Filed: Mar. 3, 2026

Related U.S. Application Data
(60) Provisional application No. 63/796,164, filed on Apr. 28, 2025.

(51) Int. Cl. H10W 76/15; H10W 42/20; H10W 72/50; H10W 74/10; H10W 76/01

(52) U.S. Cl. CPC H10W 76/15; H10W 42/276; H10W 72/50; H10W 74/111; H10W 76/01

(57) ABSTRACT

Aspects of the disclosure provide a semiconductor package and a method for producing the same. The semiconductor package includes one or more circuit features disposed on a substrate and a lid attached to the substrate. The lid includes one or more compartments configured to form one or more cavities with each cavity encapsulating a wire bond die. In various embodiments, a compartment may include a cutout configured for a close-fit accommodation of an encapsulated circuit feature within a cavity. In various embodiments, at least a portion of the cutout of the compartment includes a non-planar contour surface that accommodates a curvature of one or more wire bonds. In various embodiments, the compartment includes a rib structure configured to provide structural rigidity for the lid. In various embodiments, a wireless device includes the disclosed semiconductor package.

### CROSS-REFERENCE TO RELATED APPLICATION

This application claims priority to U.S. Patent Application No. 63/796,164, filed Apr. 28, 2025, all of which is incorporated by reference herein in its entirety.

### TECHNICAL FIELD

The present disclosure relates generally to air cavity electronic packages, and in particular, relates to a semiconductor package and a method for preparing a semiconductor package having a lid for micro-electro-mechanical systems (MEMS) and radio frequency (RF) applications.

### BACKGROUND

Advanced semiconductor electronics are typically assembled using cutting-edge manufacturing techniques. As electronic systems become more compact and engineered to operate at higher frequencies, MEMS or high frequency RF packages tend to require air cavities to maintain the functionality of the devices. However, a package-level air cavity solution can complicate module design by adding a host of new design considerations to existing manufacturing techniques. Furthermore, many features that have been developed for over-molded packages cannot be implemented on air cavity packages. For example, when implementing an air cavity package solution, a keep-out zone around the periphery of the package is required for the periphery area of the component where the lid will be attached. Thus, the lid needs to be bigger to accommodate such package, and thus, an oversized lid may be required for a given module size. In addition, a compartmental shielding may also be difficult for some air cavity packages because the standard methods rely on a process flow with an over-molding step. Moreover, the lid may also deform or “pillow” from internal pressure after a customer reflow step during the preparation of the semiconductor package. Thus, there is a need for an improved method for preparing a semiconductor package having a lid for various air cavity packages.

### SUMMARY

Embodiments of the present disclosure include advanced semiconductor packaging techniques with a lid designed for MEMS and RF semiconductor packages. Aspects of the disclosure advantageously provide a semiconductor package and one or more methods for preparing a semiconductor package having a lid for various air cavity packages and applications.

In an exemplary aspect, a semiconductor package is provided. The semiconductor package includes one or more circuit features disposed on a substrate; and a lid attached to the substrate, the lid comprising one or more compartments configured to form one or more cavities with each cavity encapsulating a circuit feature of the one or more circuit features.

In one or more embodiments, a compartment of the one or more compartments of the lid is configured for a close-fit accommodation of an encapsulated circuit feature in a cavity, wherein the compartment comprises a cutout configured for a close-fit accommodation of the encapsulated circuit feature within the cavity. In one or more embodiments, the encapsulated circuit feature includes a wire bond die and one or more wire bonds attached to the wire bond die. In one or more embodiments, at least a portion of the cutout of the compartment accommodates a curvature of the one or more wire bonds. In one or more embodiments, at least a portion of the cutout of the compartment comprises a non-planar contour surface that accommodates a curvature of the one or more wire bonds. In one or more embodiments, the compartment further includes a wall that is coated with an electromagnetic shielding material.

In one or more embodiments, the one or more compartments comprise two compartments configured to form two cavities, with each cavity encapsulating a circuit feature of the one or more circuit features, wherein a wall of each of the two compartments is coated with an electromagnetic shielding material such that the electromagnetic shielding material provides electromagnetic shielding between two circuit features.

In one or more embodiments, a compartment of the one or more compartments of the lid is configured for a close-fit accommodation of an encapsulated circuit feature in a cavity, wherein the compartment comprises a rib structure configured to provide structural rigidity for the lid, and wherein the rib structure is further configured for providing a close-fit accommodation of the encapsulated circuit feature within the cavity.

In one or more embodiments, a wireless device may include the semiconductor package as disclosed herein.

In an exemplary aspect, a method for producing a semiconductor package is provided. The method includes forming a lid comprising one or more compartments; disposing one or more circuit features to a substrate; and attaching the lid to the substrate such that the one or more compartments form one or more cavities with each cavity encapsulating a circuit feature of the one or more circuit features.

In one or more embodiments, forming the lid comprises molding a mold material to form the lid wherein a compartment of the one or more compartments of the lid comprises a cutout configured to at least partially accommodate a curvature of one or more wire bonds. In one or more embodiments, forming the lid comprises coating an electromagnetic shielding material on a wall of the one or more compartments of the lid.

In one or more embodiments, a compartment of the one or more compartments of the lid is configured for a close-fit accommodation of an encapsulated circuit feature in a cavity, wherein the compartment comprises a cutout configured for a close-fit accommodation of the encapsulated circuit feature within the cavity. In one or more embodiments, the encapsulated circuit feature includes a wire bond die and one or more wire bonds attached to the wire bond die. In one or more embodiments, at least a portion of the cutout of the compartment comprises a non-planar contour surface that accommodates a curvature of the one or more wire bonds.

In one or more embodiments, the one or more compartments comprise two compartments configured to form two cavities, with each cavity encapsulating a circuit feature of the one or more circuit features, wherein a wall of each of the two compartments is coated with an electromagnetic shielding material such that the electromagnetic shielding material provides electromagnetic shielding between two circuit features.

In one or more embodiments, a compartment of the one or more compartments of the lid is configured for a close-fit accommodation of an encapsulated circuit feature in a cavity, wherein the compartment comprises a rib structure configured to provide structural rigidity for the lid, and wherein the rib structure is further configured for providing a close-fit accommodation of the encapsulated circuit feature within the cavity.

In one or more embodiments, a wireless device may include the semiconductor package produced via the method as disclosed herein.

In an exemplary aspect, a wireless device is provided. The wireless device may include a semiconductor package, which includes a semiconductor package comprising one or more circuit features disposed on a substrate, and a lid attached to the substrate, wherein the lid comprises one or more compartments configured to form one or more cavities with each cavity encapsulating a circuit feature of the one or more circuit features.

In one or more embodiments, a compartment of the one or more compartments of the lid comprises a cutout configured for a close-fit accommodation of an encapsulated circuit feature within a cavity. In one or more embodiments, the encapsulated circuit feature includes a wire bond die and one or more wire bonds attached to the wire bond die. In one or more embodiments, at least a portion of the cutout of the compartment comprises a non-planar contour surface that accommodates a curvature of the one or more wire bonds. In one or more embodiments, the compartment further includes a wall that is coated with an electromagnetic shielding material.

In one or more embodiments, the one or more compartments comprise two compartments configured to form two cavities, with each cavity encapsulating a circuit feature of the one or more circuit features, wherein a wall of each of the two compartments is coated with an electromagnetic shielding material such that the electromagnetic shielding material provides electromagnetic shielding between two circuit features.

In one or more embodiments, a compartment of the one or more compartments of the lid is configured for a close-fit accommodation of an encapsulated circuit feature in a cavity, wherein the compartment comprises a rib structure configured to provide structural rigidity for the lid, and wherein the rib structure is further configured for providing a close-fit accommodation of the encapsulated circuit feature within the cavity.

Additional aspects, embodiments, implementations, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1A illustrates a cross-sectional view of an example semiconductor package, according to aspects of the present disclosure.

FIG. 1B illustrates a cross-sectional view of a traditional semiconductor package, according to aspects of the present disclosure.

FIG. 1C illustrates a top schematic view of the example semiconductor package of FIG. 1A, according to aspects of the present disclosure.

FIG. 1D illustrates a bottom-up view of the lid of the example semiconductor package of FIG. 1A, according to aspects of the present disclosure.

FIG. 2A illustrates a cross-sectional view of an example semiconductor package, according to aspects of the present disclosure.

FIG. 2B illustrates a bottom view of the lid of the example semiconductor package of FIG. 2A, according to aspects of the present disclosure.

FIG. 3A illustrates a cross-sectional view of an example semiconductor package, according to aspects of the present disclosure.

FIG. 3B illustrates a bottom view of the lid of the example semiconductor package of FIG. 3A, according to aspects of the present disclosure.

FIG. 4 illustrates a flowchart for a method for producing a semiconductor package, according to aspects of the present disclosure.

FIG. 5 illustrates an electronic device or a wireless device comprising a semiconductor package, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

Embodiments of the present disclosure include advanced semiconductor manufacturing methodologies for preparing a semiconductor package having a lid (e.g., a lid) for micro-electro-mechanical systems (MEMS) and radio frequency (RF) applications. In some embodiments, the disclosed semiconductor package may include a lid cutout within the lid that can accommodate placements of a die within the lid outline, thereby allowing for smaller package sizes by providing relief for components that would otherwise interfere with the lid. In such implementations, the disclosed lid configuration can shorten the RF path by allowing bond wires to be placed closer to the edge of the package. In some embodiments, the disclosed semiconductor package may include an electromagnetic interference (EMI) shielding in one or more compartments of the lid that encase individual dies disposed on a substrate in one or more areas of the semiconductor package. The disclosed EMI shielding in the package can increase isolation between individual RF devices within the semiconductor package, thereby mitigating electromagnetic interference and crosstalk, which are common issues in densely packed electronic circuits. The disclosed EMI shielding approach can help improve isolation between these devices or between different function blocks, ensuring that each device operates within its designated electromagnetic environment, thus improving overall system performance and reliability. In some embodiments, the use of rib structures within the lid can help with lid rigidity, e.g., reducing ceiling flexure of the lid, by stiffening the lid ceiling with various rib structures that allow for potentially thinner lid ceilings. This helps prevent or resist flexure of the lid under pressure, which can cause “pillowing” after customer reflow.

Various embodiments of the disclosure provide a semiconductor package and one or more methods for preparing a semiconductor package having a lid for various air cavity packages and applications. In various embodiments, a semiconductor package may include one or more circuit features disposed on a substrate and a lid or a lid attached to the substrate, wherein the lid includes one or more compartments configured to form one or more cavities with each cavity encapsulating a circuit feature of the one or more circuit features. The compartments of the lid may be configured for a close-fit accommodation of an encapsulated circuit feature in a cavity, wherein the compartment comprises a cutout configured for a close-fit accommodation of the encapsulated circuit feature within the cavity. In one or more embodiments, the encapsulated circuit feature includes a wire bond die and wire bonds attached to the wire bond die. The cutout of the compartment may accommodate a curvature of the wire bonds or may include a non-planar contour surface that accommodates a curvature of the wire bonds. The compartments may also include a wall that is coated with an electromagnetic shielding material. The compartments may also include a rib structure configured to provide structural rigidity for the lid and to provide a close-fit accommodation for the wire bonds attached to the encapsulated circuit feature within the cavity.

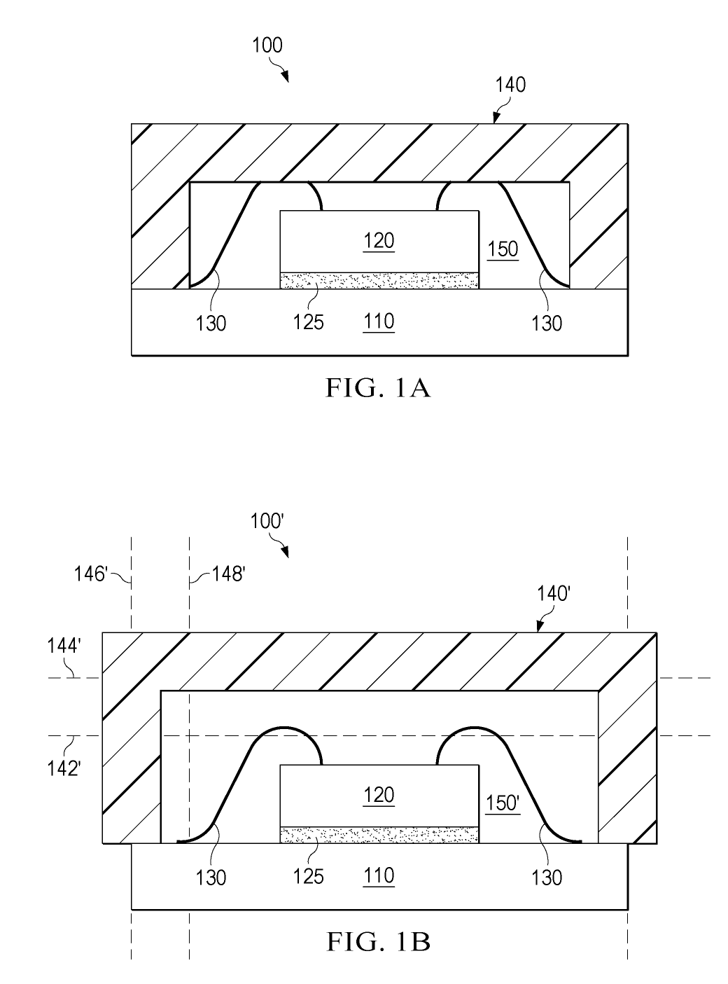

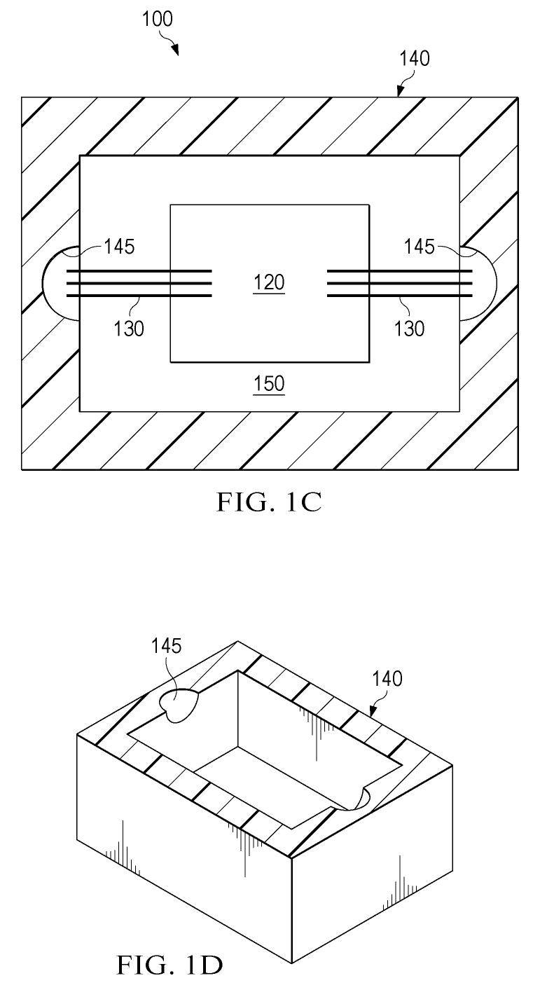

To further demonstrate the disclosed semiconductor package and methods for preparing such packages, various embodiments of packages and preparation methodologies are described below in further detail with respect to the FIGS. 1A, 1C, 1D, 2A, 2B, 3A, 3B, 4, and 5.

FIGS. 1A, 1C, and 1D illustrate an example semiconductor package 100 and its components, according to aspects of the present disclosure. FIG. 1B, on the other hand, illustrates a cross-sectional view of a traditional semiconductor package 100’ to compare against the disclosed semiconductor package 100 of FIG. 1A. In particular, FIG. 1A illustrates a cross-sectional view of the semiconductor package 100, FIG. 1C illustrates a top schematic view of a lid 140 of the semiconductor package of 100, and FIG. 1D illustrates a bottom-up view of the lid 140 of the semiconductor package 100, according to aspects of the present disclosure. In one or more embodiments, the semiconductor package 100 described with respect to FIGS. 1A, 1C, and 1D may include a wide band gap semiconductor package having a lid for micro-electro-mechanical systems (MEMS) and radio frequency (RF) applications, with an electromagnetic interference shielding and/or a rib structure for added rigidity of the lid. In some embodiments, the semiconductor package 100 may be produced or manufactured using advanced semiconductor packaging techniques as disclosed herein.

As illustrated in FIGS. 1A, 1C, and 1D, the semiconductor package 100 may include a substrate 110 (may also be referred to herein as a laminate) and a circuit feature 120, which is disposed on the substrate 110 via a die attach material 125. Although circuit feature 120 is shown as a wire bond die for illustrative purposes, the circuit feature 120 may include more than one circuit features, including but not limited to, flip chip dies, epoxy-attached dies, or other surface mounted devices and components. In one or more embodiments, the substrate 110 may include a plated heat spreader, or other suitable laminated substrate. As depicted in FIG. 1A, the semiconductor package 100 also includes wire bonds 130, which electrically connect the circuit feature 120, which is illustrated as a wire bond die, to the substrate 110. The semiconductor package 100 further includes a lid 140 attached to the substrate 110. The lid 140 is attached to the substrate 110 such that a cavity 150 is formed to encapsulate the circuit feature/wire bond die 120 and the wire bonds 130 within the cavity 150. In one or more embodiments, the lid 140 includes one or more cut outs to provide a close-fit accommodation for one or more circuit features 120.

In the cross-sectional view shown in FIG. 1A, the wire bonds 130 appear to be overlapping with the lid 140, indicating that they may be in contact with the lid 140. However, that is not the case, as illustrated by the top schematic view of the semiconductor package 100 shown in FIG. 1C and the bottom-up view of the lid 140 shown in FIG. 1D. FIGS. 1C and 1D clearly illustrate that the lid 140 includes a cutout 145 that can accommodate the curvature of the wire bonds 130, while enabling a close-fit accommodation of the circuit feature 120. In other words, the disclosed lid 140 is designed and configured for a close-fit accommodation of the wire bonds 130 and the circuit feature 120. In one or more embodiments, at least a portion of the cutout 145 of the lid 140 accommodates a curvature of the wire bonds 130. In one or more embodiments, at least a portion of the cutout 145 may include a non-planar contour surface that can accommodate a curvature of the wire bonds 130, as shown in FIGS. 1C and 1D.

Although the illustration shown in FIGS. 1A, 1C, and 1D depicts wire bonds 130 as the interfering element, any other interfering elements, including but not limited to, a surface mount device, can interfere with the lid 140 or the semiconductor package 100. Thus, the embodiments disclosed herein can be used to engineer or design the lid 140 such that any other interfering elements can be accommodated within the lid 140 and the semiconductor package 100.

In contrast to the disclosed semiconductor package 100, the traditional semiconductor package 100’ of FIG. 1B is depicted with a traditional lid 140’, whose dimensions require to be larger than those of the disclosed lid 140, simply to prevent contacting the wire bonds 130 and to prevent interfering with the RF paths of the circuit feature 120. Thus, to accommodate the same components of the circuit feature 120, wire bonds 130, and substrate 110, the traditional lid 140’ of FIG. 1B has larger dimensions that grow beyond the dashed lines 142’, 144’, 146’, and 148’ that mark the dimensions of the disclosed lid 140.

In one or more embodiments, the lid 140 may include a flame-retardant material, such as FR4 material. In one or more embodiments, the lid 140 may be a lid that is formed from molding a mold material or machined from a block of material. Although shown in the cross-sectional view of FIG. 1A as a single chamber/compartment lid, the lid 140 may include a plurality of compartments or additional features, such as an electromagnetic shielding, as discussed further below.

Although shown as a single circuit feature 120 and the lid 140 as a single-chamber lid or single-compartment lid in FIGS. 1A, 1C, and 1D, the lid 140 can include multiple compartments, with each compartment acting as a chamber to accommodate a single circuit feature 120. In other words, the lid 140 can include a plurality of chambers, with each chamber having a cutout, like the cutout 145, meaning there can be multiple compartments with multiple cutouts to accommodate multiple circuit features that are disposed on the substate 110.

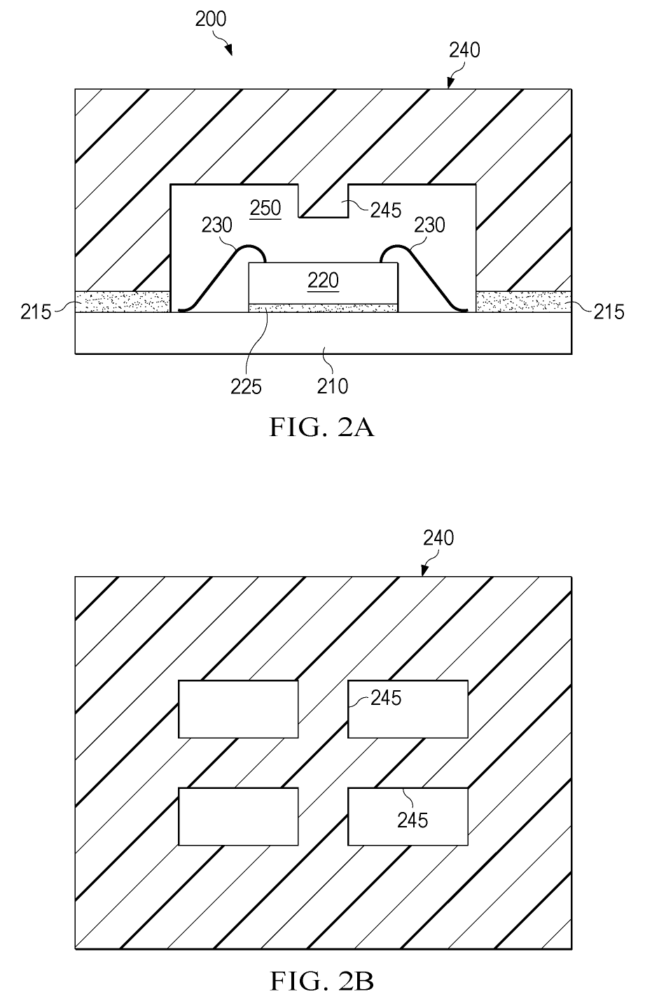

FIGS. 2A and 2B illustrate a cross-sectional view of a semiconductor package 200 and a lid 240 of the semiconductor package 200, respectively, according to aspects of the present disclosure. In one or more embodiments, the semiconductor package 200 described with respect to FIG. 2A may include a wide band gap semiconductor package for MEMS and RF applications, with an electromagnetic interference shielding and/or a rib structure for added rigidity of the lid. In some embodiments, the semiconductor package 200 may be produced or manufactured using advanced semiconductor packaging techniques as disclosed herein.

As illustrated in FIGS. 2A and 2B, the semiconductor package 200 includes a substrate 210 and a circuit feature 220 disposed on the substrate 210 via a die attach material 225. In one or more embodiments, the substrate 210 may include a plated heat spreader, or other suitable laminated substrate. As depicted in FIG. 2A, the semiconductor package 200 also includes wire bonds 230, which electrically connect the circuit feature 220 to the substrate 210. The semiconductor package 200 further includes a lid 240, which is attached to the substrate 210. As shown in FIG. 2A, the lid 240 is attached to the substrate 210 such that a cavity 250 is formed to encapsulate the circuit feature 220 and the wire bonds 230 within the cavity 250.

As shown in FIG. 2B, the lid 240 includes a rib structure 245 to provide structural rigidity to the lid 240. In one or more embodiments, the use of rib structure 245 within the lid 240 can help with lid rigidity, for example, with reducing ceiling flexure of the lid 240, or by stiffening the ceiling of the lid 240 with various rib structures that allow for potentially thinner lid ceilings. With the disclosed rib structure 245, the lid 240 can help prevent or resist flexure of the lid 240 under pressure, which can cause “pillowing” when additional processes, such as a reflow step, are performed.

In one or more embodiments, the lid 240 may include a flame-retardant material, such as FR4 material. In one or more embodiments, the lid 240 may be a lid that is formed from molding a mold material. In one or more embodiments, the lid 240 is to form the rib structure 245 within the lid 240.

In one or more embodiments, the lid 240 may include a cutout, like the cutout 145, although not illustrated in FIGS. 2A or 2B. Similarly, although not shown, the lid 240 may include a plurality of chambers, with each chamber having a cutout, like the cutout 145, meaning there can be multiple compartments with multiple cutouts to accommodate multiple circuit features that are disposed on the substate 210, in accordance with one or more embodiments.

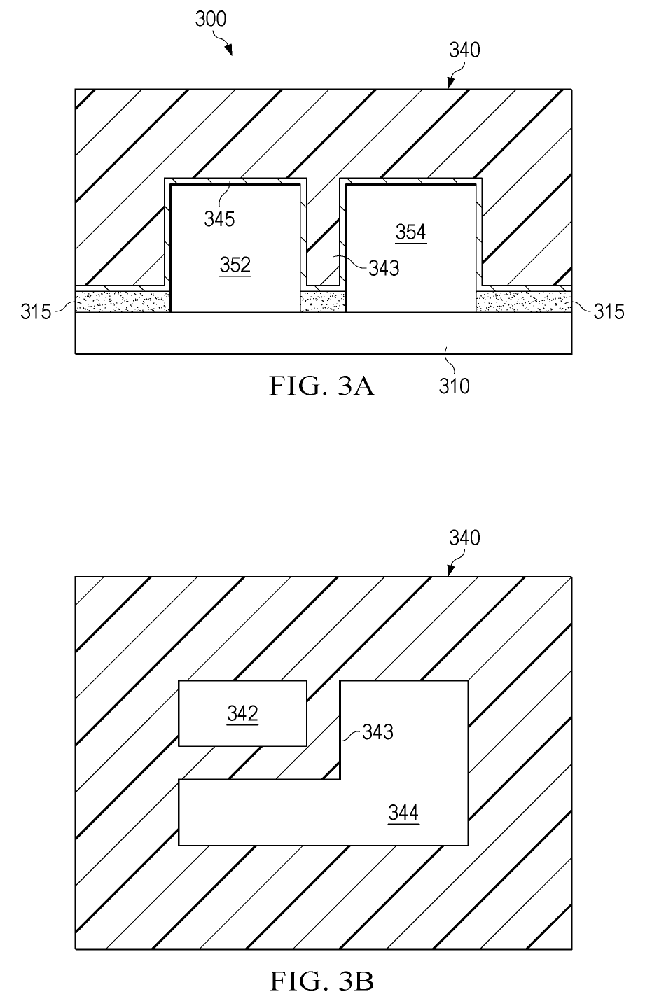

FIGS. 3A and 3B illustrate a cross-sectional view of a semiconductor package 300 and a lid 340 of the semiconductor package 300, respectively, according to aspects of the present disclosure. In one or more embodiments, the semiconductor package 300 described with respect to FIG. 3A may include a wide band gap semiconductor package for MEMS and RF applications, with an electromagnetic interference shielding and/or a rib structure for added rigidity of the lid. In some embodiments, the semiconductor package 300 may be produced or manufactured using advanced semiconductor packaging techniques as disclosed herein.

As illustrated in FIGS. 3A and 3B, the semiconductor package 300 includes a substrate 310 and other components (not shown), such as, a wire bond die, wire bonds, etc. In one or more embodiments, the substrate 310 may include a plated heat spreader, or other suitable laminated substrate. As depicted in FIG. 3A, the semiconductor package 300 includes a lid 340, which is attached to the substrate 310 via a lid attach material 315. As shown in FIG. 3B, the lid 340 includes one or more compartments 342/344 that are formed by having one or more dividers 343 formed inside the lid 340. The one or more compartments 342/344 are configured to form one or more cavities 352/354 when the lid 340 is attached to the substrate 310, with each cavity capable of encapsulating a circuit feature (not shown), as illustrated in FIG. 3A.

As further illustrate in FIG. 3A, the one or more compartments 342/344 are coated with an electromagnetic shielding material 345, which can help reduce electromagnetic interference (EMI) during operation of the semiconductor package 300. In one or more embodiments, the one or more compartments 342/344 form two cavities 352/354, with each cavity encapsulating a circuit feature and a wall of each of the two compartments 342/344 is coated with the electromagnetic shielding material 345 to provide electromagnetic shielding between two circuit features (not shown).

In one or more embodiments, the lid 340 may include a flame-retardant material, such as FR4 material. In one or more embodiments, the lid 340 may be a lid that is formed from molding a mold material. In one or more embodiments, the lid 340 is to form one or more compartments 342/344 within the lid 340.

In one or more embodiments, the lid 340 may include a cutout, like the cutout 145, although not illustrated in FIGS. 3A or 3B. Similarly, although not shown, the lid 340 may include a rib structure, like the rib structure 245, to provide structural rigidity to the lid 340, in accordance with one or more embodiments.

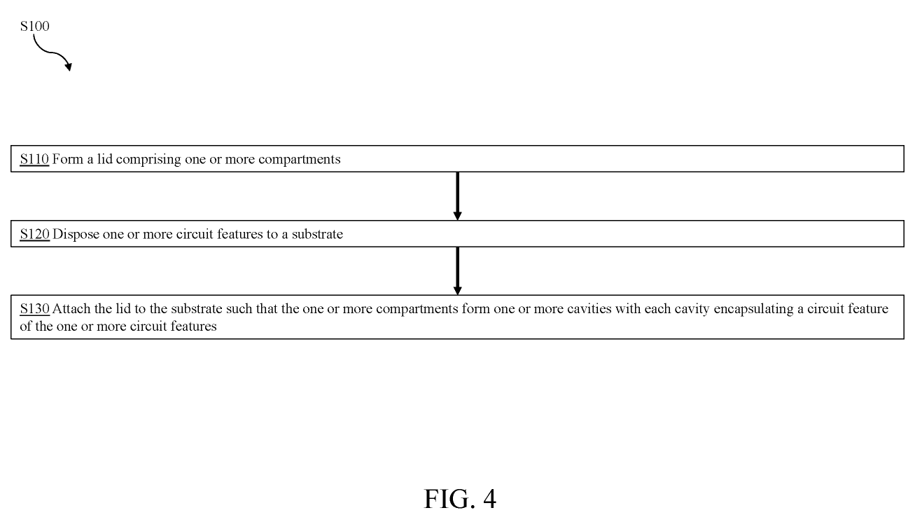

FIG. 4 illustrates a flowchart for a method S100 for producing an example semiconductor package, according to aspects of the present disclosure. In one or more embodiments, the semiconductor package formed via the method S100 may include a semiconductor package for MEMS and RF applications, with an electromagnetic interference shielding and/or a rib structure for added rigidity of the lid, such as the semiconductor packages 100, 200, and 300, as described with respect to FIGS. 1A, 1C, 1D, 2A, 2B, 3A, and 3B.

As shown in FIG. 4, the method S100 includes, at step S110, forming a lid comprising one or more compartments; at step S120, disposing one or more circuit features to a substrate; and at step S130, attaching the lid to the substrate such that the one or more compartments form one or more cavities with each cavity encapsulating a circuit feature of the one or more circuit features.

In one or more embodiments of the method S100, the lid may include a lid, such as the lids 140, 240, and/or 340, the compartments include compartments, such as the compartments 342/344, the one or more circuit features include one or more circuit features, such as the one or more circuit features 120 or 220 , the substrate includes a substrate, such as the substrates 110, 210, and 310, the one or more cavities include one or more cavities, such as the one or more cavities 150, 250, 352, and/or 354, as described with respect to FIGS. 1A, 1C, 1D, 2A, 2B, 3A, and 3B.

In one or more embodiments of the method S100, the encapsulated circuit feature includes a wire bond die and one or more wire bonds attached to the wire bond die. In one or more embodiments, a compartment of the one or more compartments of the lid comprises a cutout configured to at least partially accommodate a curvature of one or more wire bonds. In one or more embodiments, the cutout includes a cutout, such as the cutout 145, the one or more wire bonds include one or more wire bonds, such as the one or more wire bonds 130 or 230, as described with respect to FIGS. 1A, 1C, 1D, 2A, and 2B.

In one or more embodiments of the method S100, forming the lid comprises coating an electromagnetic shielding material on a wall of the one or more compartments of the lid. In one or more embodiments, the electromagnetic shielding material includes an electromagnetic shielding material, such as the electromagnetic shielding material 345, as described with respect to FIGS. 3A and 3B.

In one or more embodiments of the method S100, a compartment of the one or more compartments of the lid may be configured for a close-fit accommodation of an encapsulated circuit feature in a cavity, wherein the compartment comprises a cutout, such as the cutout 145 shown in FIGS. 1C and 1D, configured for a close-fit accommodation of the encapsulated circuit feature within the cavity. In one or more embodiments, the encapsulated circuit feature includes a wire bond die and one or more wire bonds attached to the wire bond die. In one or more embodiments, at least a portion of the cutout of the compartment may include a non-planar contour surface, such as that of the cutout 145 shown in FIGS. 1C and 1D, that accommodates a curvature of the one or more wire bonds.

In one or more embodiments of the method S100, the one or more compartments comprise two compartments configured to form two cavities, with each cavity encapsulating a circuit feature of the one or more circuit features, wherein a wall of each of the two compartments is coated with an electromagnetic shielding material such that the electromagnetic shielding material provides electromagnetic shielding between two circuit features. In one or more embodiments, the electromagnetic shielding material includes an electromagnetic shielding material, such as the electromagnetic shielding material 345, as described with respect to FIGS. 3A and 3B.

In one or more embodiments of the method S100, a compartment of the one or more compartments of the lid is configured for a close-fit accommodation of an encapsulated circuit feature in a cavity, wherein the compartment comprises a rib structure configured to provide structural rigidity for the lid, and wherein the rib structure is further configured for providing a close-fit accommodation of the encapsulated circuit feature within the cavity. In one or more embodiments, the rib structure includes a rib structure, such as the rib structure 245, as described with respect to FIGS. 2A and 2B.

In one or more embodiments, a wireless device may include the semiconductor package produced via the method S100 as disclosed herein.

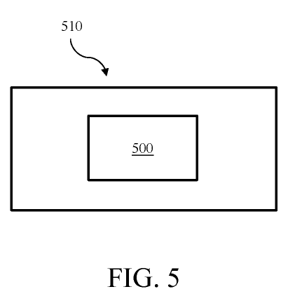

FIG. 5 illustrates an electronic device or a wireless device 510 comprising a semiconductor package 500, according to aspects of the present disclosure. In some implementations, the electronic device or wireless device 510 may include, for example, but not limited to, a computer, a cellular device, a satellite communication device, a wi-fi device, a radar, a global position system device, or any electronic device. In one or more embodiments, the semiconductor package 500 may be produced in accordance with the method S100 described with respect to FIG. 4, and/or may include a semiconductor package for MEMS and RF applications, with an electromagnetic interference shielding and/or a rib structure for added rigidity of the lid, such as the semiconductor packages 100, 200, and 300, as described with respect to FIGS. 1A, 1C, 1D, 2A, 2B, 3A, and 3B. The semiconductor package may implement any RF circuitry used in wireless applications, as an example, such as one or more RF power amplifiers; and the semiconductor package may be coupled to other circuitry for implementing a wireless application, such as a baseband processor or other types of processors.

In one or more embodiments, the wireless device 510 may include the semiconductor package 500. In one or more embodiments, the semiconductor package 500 includes one or more circuit features, such as circuit features 120 and 220, disposed on a substrate, such as substrates 110, 210, and 310, and a lid, such as lids 140, 240, and 340, attached to the substrate, wherein the lid comprises one or more compartments, such as compartments 342 and 344, configured to form one or more cavities, such as cavities 150, 250, 352, and 354, with each cavity encapsulating a circuit feature of the one or more circuit features. In one or more embodiments, the encapsulated circuit feature includes a wire bond die and one or more wire bonds, such as wire bonds 130 and 230, attached to the wire bond die.

In one or more embodiments of the wireless device 510, a compartment of the one or more compartments of the lid comprises a cutout, such as cutout 145, configured for a close-fit accommodation of one or more wire bonds, such as wire bonds 130 and 230, attached to an encapsulated circuit feature within a cavity. In one or more embodiments, at least a portion of the cutout of the compartment comprises a non-planar contour surface, e.g., of a cutout 145, that accommodates a curvature of the one or more wire bonds. In one or more embodiments, the compartment further includes a wall that is coated with an electromagnetic shielding material, such as the electromagnetic shielding material 345.

In one or more embodiments of the wireless device 510, the one or more compartments comprise two compartments configured to form two cavities, with each cavity encapsulating a circuit feature of the one or more circuit features, wherein a wall of each of the two compartments is coated with an electromagnetic shielding material such that the electromagnetic shielding material provides electromagnetic shielding between two circuit features.

In one or more embodiments of the wireless device 510, a compartment of the one or more compartments of the lid is configured for a close-fit accommodation of an encapsulated circuit feature in a cavity, wherein the compartment comprises a rib structure, such as the rib structure 245, configured to provide structural rigidity for the lid, and wherein the rib structure is further configured for providing a close-fit accommodation of the encapsulated circuit feature within the cavity.

In one or more embodiments, the semiconductor package 500 of the wireless device 510 may be produced via the method S100, as described with respect to FIG. 4.

Various embodiments of the disclosure advantageously provide a semiconductor package, such as the semiconductor packages 100, 200, 300, as described with respect to FIGS. 1A, 1C, 1D, 2A, 2B, 3A, and 3B, and a method, such as the method S100, as described with respect to FIG. 4, of producing a semiconductor package for MEMS and RF applications, with an electromagnetic interference shielding and/or a rib structure for added rigidity of the lid.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A semiconductor package, comprising:
one or more circuit features disposed on a substrate; and
a lid attached to the substrate, the lid comprising one or more compartments configured to form one or more cavities with each cavity encapsulating a circuit feature of the one or more circuit features.

2. The semiconductor package of claim 1, wherein a compartment of the one or more compartments of the lid is configured for a close-fit accommodation of an encapsulated circuit feature in a cavity, wherein the compartment comprises a cutout configured for a close-fit accommodation of the encapsulated circuit feature within the cavity.

3. The semiconductor package of claim 2, wherein the encapsulated circuit feature includes a wire bond die and one or more wire bonds attached to the wire bond die and wherein at least a portion of the cutout of the compartment accommodates a curvature of the one or more wire bonds.

4. The semiconductor package of claim 2, wherein the encapsulated circuit feature includes a wire bond die and one or more wire bonds attached to the wire bond die and wherein at least a portion of the cutout of the compartment comprises a non-planar contour surface that accommodates a curvature of the one or more wire bonds.

5. The semiconductor package of claim 2, wherein the compartment further includes a wall that is coated with an electromagnetic shielding material.

6. The semiconductor package of claim 1, wherein the one or more compartments comprise two compartments configured to form two cavities, with each cavity encapsulating a circuit feature of the one or more circuit features, wherein a wall of each of the two compartments is coated with an electromagnetic shielding material such that the electromagnetic shielding material provides electromagnetic shielding between two circuit features.

7. The semiconductor package of claim 1, wherein a compartment of the one or more compartments of the lid is configured for a close-fit accommodation of an encapsulated circuit feature in a cavity, wherein the compartment comprises a rib structure configured to provide structural rigidity for the lid, and wherein the rib structure is further configured for providing a close-fit accommodation of the encapsulated circuit feature within the cavity.

8. A wireless device comprising the semiconductor package of claim 1.

9. A method for producing a semiconductor package, comprising:
forming a lid comprising one or more compartments;
disposing one or more circuit features to a substrate; and
attaching the lid to the substrate such that the one or more compartments form one or more cavities with each cavity encapsulating a circuit feature of the one or more circuit features.

10. The method of claim 9, wherein the encapsulated circuit feature includes a wire bond die and one or more wire bonds attached to the wire bond die and wherein a compartment of the one or more compartments of the lid comprises a cutout configured to at least partially accommodate a curvature of one or more wire bonds.

11. The method of claim 9, wherein forming the lid comprises coating an electromagnetic shielding material on a wall of the one or more compartments of the lid.

12. The method of claim 9, wherein a compartment of the one or more compartments of the lid is configured for a close-fit accommodation of an encapsulated circuit feature in a cavity, wherein the compartment comprises a cutout configured for a close-fit accommodation of the encapsulated circuit feature within the cavity.

13. The method of claim 12, wherein the encapsulated circuit feature includes a wire bond die and one or more wire bonds attached to the wire bond die and wherein at least a portion of the cutout of the compartment comprises a non-planar contour surface that accommodates a curvature of the one or more wire bonds.

14. The method of claim 9, wherein the one or more compartments comprise two compartments configured to form two cavities, with each cavity encapsulating a circuit feature of the one or more circuit features, wherein a wall of each of the two compartments is coated with an electromagnetic shielding material such that the electromagnetic shielding material provides electromagnetic shielding between two circuit features.

15. The method of claim 14, wherein a compartment of the one or more compartments of the lid is configured for a close-fit accommodation of an encapsulated circuit feature in a cavity, wherein the compartment comprises a rib structure configured to provide structural rigidity for the lid, and wherein the rib structure is further configured for providing a close-fit accommodation of the encapsulated circuit feature within the cavity.

16. A wireless device comprising:
a semiconductor package comprising:
one or more circuit features disposed on a substrate, and
a lid attached to the substrate, wherein the lid comprises one or more compartments configured to form one or more cavities with each cavity encapsulating a circuit feature of the one or more circuit features.

17. The wireless device of claim 16, wherein:
a compartment of the one or more compartments of the lid comprises a cutout configured for a close-fit accommodation of an encapsulated circuit feature within a cavity, wherein the encapsulated circuit feature includes a wire bond die and one or more wire bonds attached to the wire bond die, and
at least a portion of the cutout of the compartment comprises a non-planar contour surface that accommodates a curvature of the one or more wire bonds.

18. The wireless device of claim 17, wherein the compartment further includes a wall that is coated with an electromagnetic shielding material.

19. The wireless device of claim 16, wherein the one or more compartments comprise two compartments configured to form two cavities, with each cavity encapsulating a circuit feature of the one or more circuit features, wherein a wall of each of the two compartments is coated with an electromagnetic shielding material such that the electromagnetic shielding material provides electromagnetic shielding between two circuit features.

20. The wireless device of claim 16, wherein a compartment of the one or more compartments of the lid is configured for a close-fit accommodation of an encapsulated circuit feature in a cavity, wherein the compartment comprises a rib structure configured to provide structural rigidity for the lid, and wherein the rib structure is further configured for providing a close-fit accommodation of the encapsulated circuit feature within the cavity.
